(19) United States
(12) Patent Application Publication
(10) Pub. No.: US 2026/0206187 A1
(43) Pub. Date: Jul. 16, 2026

(54) THERMAL MANAGEMENT OF AN INFORMATION HANDLING SYSTEM

(71) Applicant: Dell Products L.P., Round Rock, TX (US)

(72) Inventors: Pomin Shih, Taipei City (TW); Enoch Chen, Taipei City (TW); Travis C. North, Cedar Park, TX (US)

(21) Appl. No.: 19/021,437

(22) Filed: Jan. 15, 2025

(51) Int. Cl. H05K 7/20; G06F 1/20

(52) U.S. Cl. CPC H05K 7/20481; G06F 1/203

(57) ABSTRACT

An information handling system, including a body including a first side and a second side, the second side including an internal surface and an external surface; one or more computing elements contained within the body, the computing elements configured to generate heat proximate to the inner surface of the second side of the body; a thermal stack coupled to the inner surface of the second side of the body, the thermal stack including: an aerogel film layer; and a heat dissipating layer that is coated to the aerogel sheet such that the aerogel film layer is between the inner surface of the second side of the body and the heat dissipating layer, wherein the thermal stack is configured to reduce a skin temperature of the external surface of the second side of the body.

### BACKGROUND

### Field of the Disclosure

The disclosure relates generally to an information handling system, and in particular, thermal management of the information handling system.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Managing the skin temperature of information handling systems such as laptops and smartphones is crucial to ensure user comfort and device longevity. Effective thermal management techniques help dissipate heat generated by computing elements.

### SUMMARY

Innovative aspects of the subject matter described in this specification may be embodied in an information handling system including a body including a first side and a second side, the second side including an internal surface and an external surface; one or more computing elements contained within the body, the computing elements configured to generate heat proximate to the inner surface of the second side of the body; a thermal stack coupled to the inner surface of the second side of the body, the thermal stack including: an aerogel film layer; and a heat dissipating layer that is coated to the aerogel sheet such that the aerogel film layer is between the inner surface of the second side of the body and the heat dissipating layer, wherein the thermal stack is configured to reduce a skin temperature of the external surface of the second side of the body.

Other embodiments of these aspects include corresponding systems and apparatus.

These and other embodiments may each optionally include one or more of the following features. For instance, the thermal stack further includes a graphite sheet such that the aerogel film layer is between the graphite sheet and the heat dissipation layer. The graphite sheet is coupled to the inner surface of the second side of the body. The heat dissipating layer is 0.02 millimeters thick. The aerogel film layer is coupled to the inner surface of the second side of the body. The heat dissipating layer is formed from at least boron nitride, graphene, and carbon fiber.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 is a perspective view of the information handling system.

FIG. 3 is a side view of the information handling system, showing internal components of the information handling system.

FIG. 4 is a side view of a thermal stack, in a first implementation.

FIG. 5 is a top-down view of a body of the information handling system.

FIG. 6 is a side view of the thermal stack, in a second implementation.

FIG. 7 is a side view of the thermal stack, in a third implementation.

FIG. 8 is a bottom-up view of a keyboard of the information handling system.

### DESCRIPTION OF PARTICULAR EMBODIMENT(S)

This disclosure discusses a thermal stack that can reduce a skin temperature at an information handling system. Specifically, this disclosure discusses an information handling system comprising a body including a first side and a second side, the second side including an internal surface and an external surface; one or more computing elements contained within the body, the computing elements configured to generate heat proximate to the inner surface of the second side of the body; a thermal stack coupled to the inner surface of the second side of the body, the thermal stack including: an aerogel film layer; a heat dissipating layer that is coated to the aerogel sheet such that that the aerogel film layer is between the inner surface of the second side of the body and the heat dissipating layer, wherein the thermal stack is configured to reduce a skin temperature of the external surface of the second side of the body.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

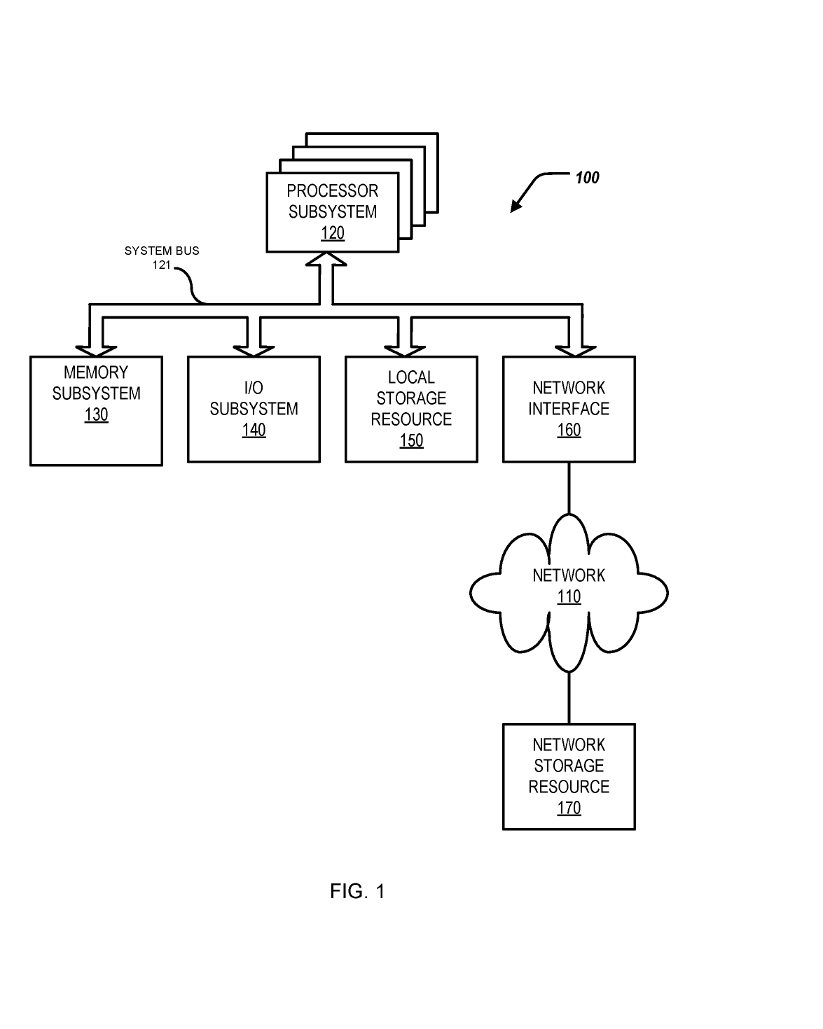

Particular embodiments are best understood by reference to FIGS. 1-8 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system 100). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

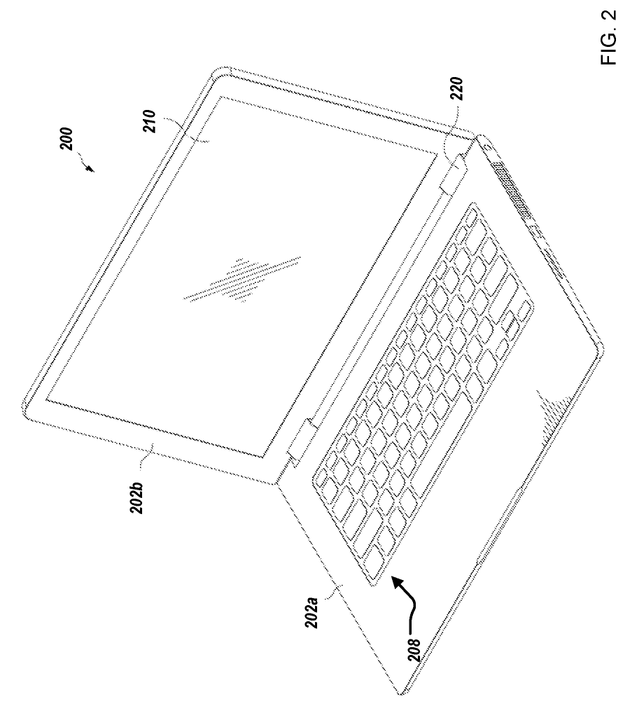

FIG. 2 illustrates a perspective view of an information handling system 200. The information handling system 200 can include a first body 202a and a second body 202b (collectively referred to as bodies 202). The first body 202a can include a keyboard 208. The second body 202b can include a display 210. A hinge 220 can couple the first body 202a to the second body 202b. In some examples, the information handling system 200 is similar to, or includes, the information handling system 100 of FIG. 1.

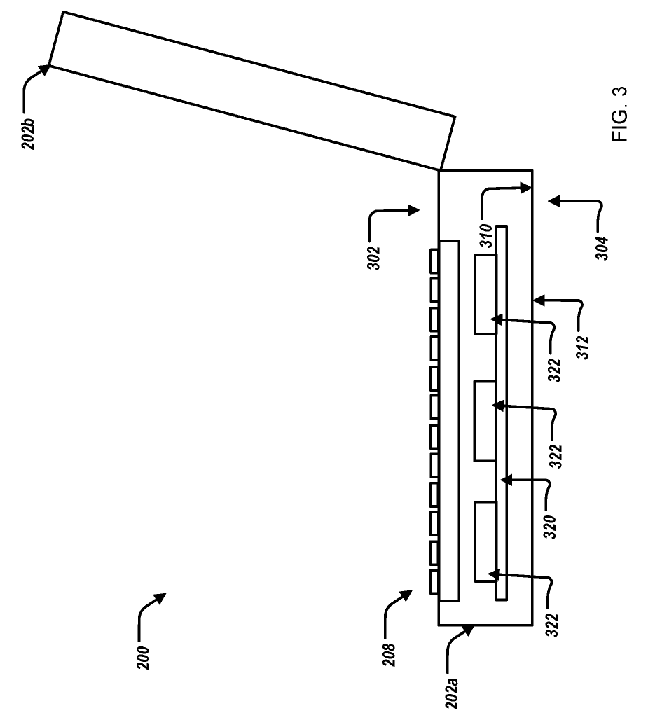

FIG. 3 illustrates a side view of the information handling system 200. The first body 202a can include a first side 302 and a second side 304. The second side 304 can include an internal surface 310 and an external surface 312. The information handling system 200 can further include a printed circuit board (PCB) 320 (or motherboard 320, or main board 320) and computing elements 322 coupled to the PCB 320. The information handling system 200 can include any number of computing elements 322. For example, the computing elements 322 can include any of the processor subsystem 120, the memory subsystem 130, the I/O subsystem 140, the local storage resource 150, and/or the network interface 160, of FIG. 1. The computing elements 322 generate heat proximate to the inner surface 310 and/or the outer surface 312 of the first body 202a. The second side 304 can be considered the “D” cover of the information handling system 200.

In short, the information handling system 200 can include a thermal stack. The thermal stack can reduce a skin temperature at the information handling system 200, described further therein.

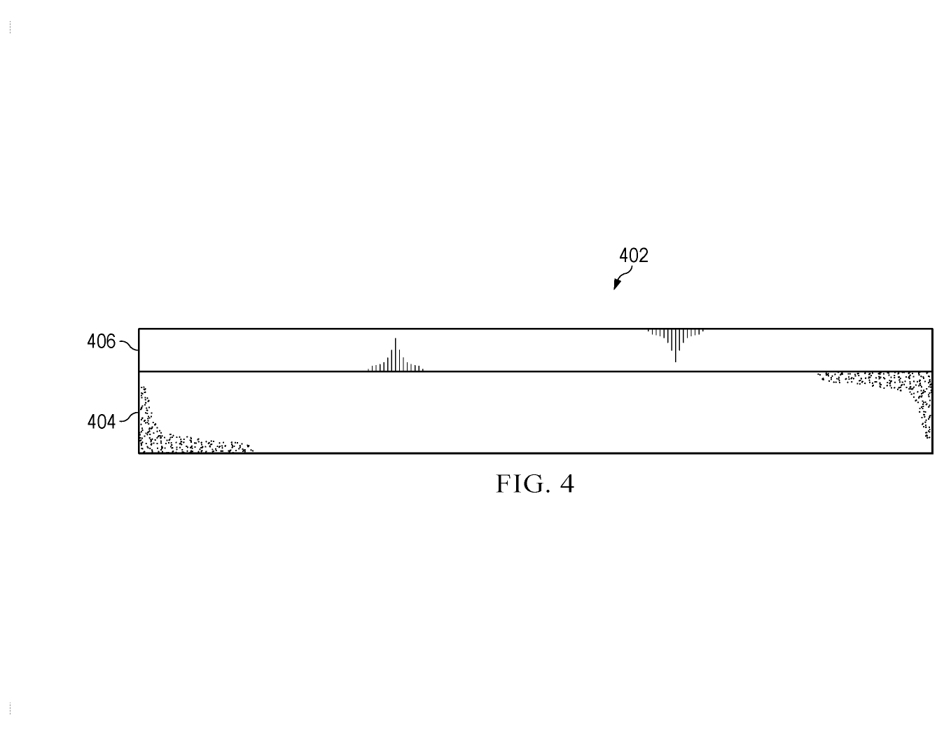

FIG. 4 is a side view of a thermal stack 402, in a first implementation. The thermal stack 402 can include an aerogel film layer 404 and a heat dissipating layer 406. The heat dissipating layer 406 is coated on the aerogel film layer 404. The aerogel film layer 404 is a thermal insulation layer, and in some examples, has a conductivity of 0.01, or approximately 0.01. In some examples, the aerogel film layer 404 is 0.1 millimeters thick, or approximately 0.1 millimeters thick.

In some examples, the heat dissipating layer 406 is formed from a combination of boron nitride, graphene, and carbon fiber. In some examples, the heat dissipating layer 406 includes adhesives. In some examples, the heat dissipating layer 406 is 0.02 millimeters thick, or approximately 0.02 millimeters thick. In some examples, the heat dissipating layer 406 includes carbon nanotubes.

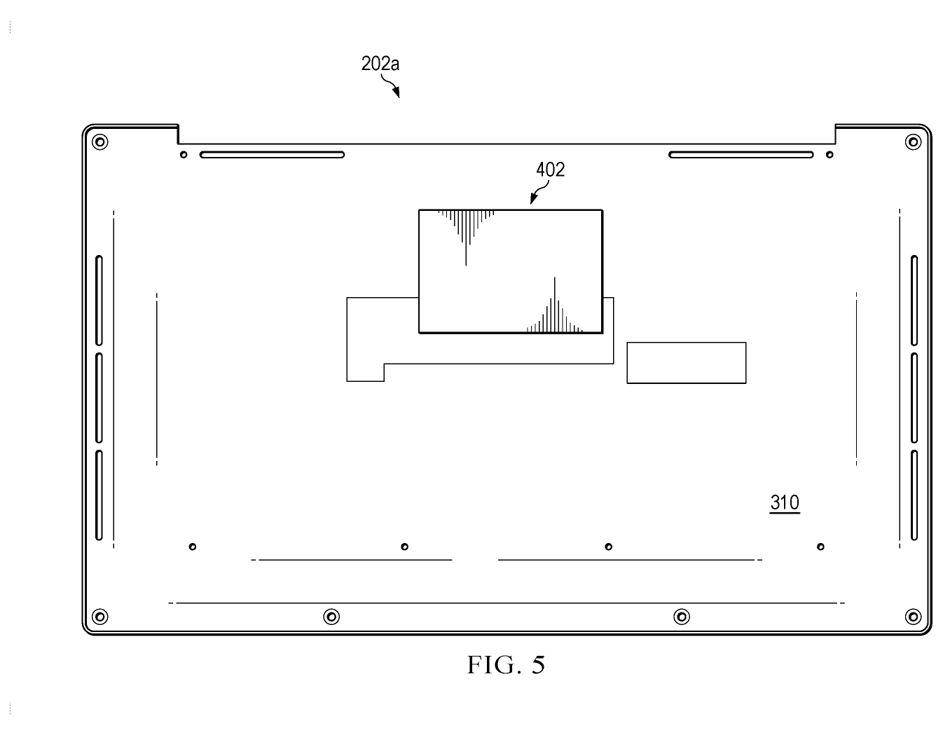

FIG. 5 is a top-down view of the first body 202a of the information handling system 200. Referring to FIGS. 3-5, in some examples, the thermal stack 402 is coupled to the inner surface 310 of the second side 304 of the first body 202a. Specifically, the aerogel film layer 404 is coupled (adhered) to the inner surface 310 of the second side 304 of the first body 202a. That is, the aerogel film layer 404 is between the inner surface 310 of the second side 304 of the first body 202a and the heat dissipating layer 406. In other words, the thermal stack 402 is coupled (adhered) to the inner surface of the “D” cover of the information handling system 200; and in particular, the aerogel film layer 404 is coupled (adhered) to the inner surface of the “D” cover of the information handling system 200.

To that end, the thermal stack 402 is configured to reduce a skin temperature of the external surface 312 of the second side 304 of the first body 202a. That is, through the combination of the insulation of the aerogel film layer 404 and the radiation of the heat dissipating layer 406, the skin temperature of the external surface 312 of the second side 304 of the first body 202a can be reduced. That is, the heat generated by the computing elements 322 can be reduced by the thermal stack 402, and in particular, through the combination of the insulation of the aerogel film layer 404 and the radiation of the heat dissipating layer 406. That is, the skin temperature of the external surface 312 of the second side 304 of the first body 202a that is a result of the heat generated by the computing elements 322 can be reduced by the thermal stack 402, and in particular, through the combination of the insulation of the aerogel film layer 404 and the radiation of the heat dissipating layer 406.

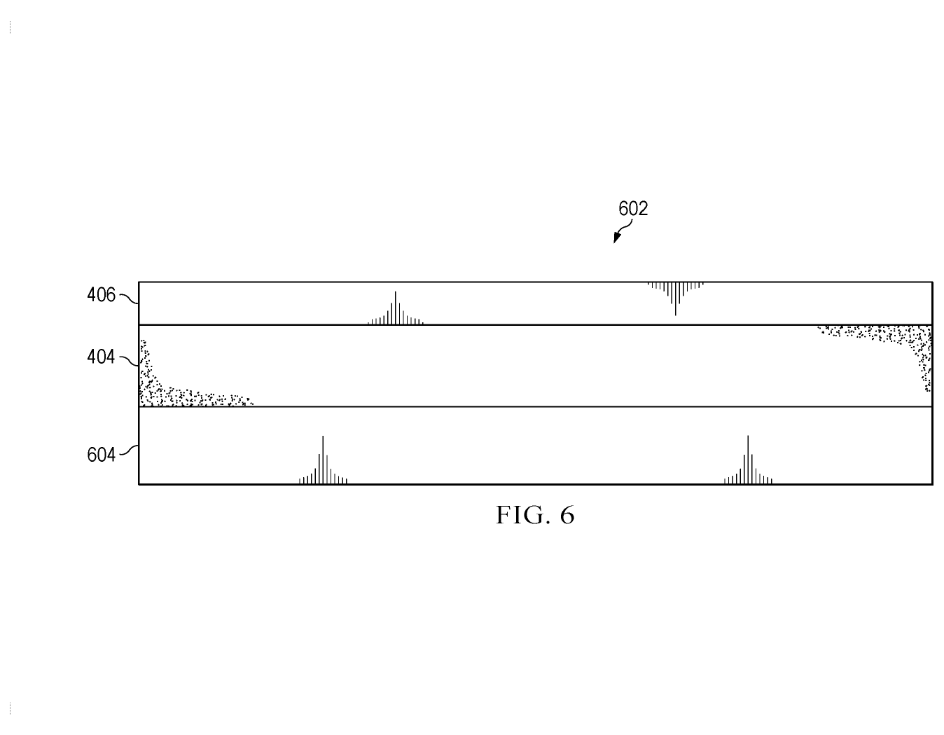

FIG. 6 is a side view of a thermal stack 602, in a second implementation. The thermal stack 602 can include the aerogel film layer 404, the heat dissipating layer 406 and a graphite sheet 604. The aerogel film layer 404 can be positioned between the heating dissipating layer 406 and the graphite sheet 604. In some examples, the graphite sheet 604 is 0.1 millimeters thick, or approximately 0.1 millimeters thick. Referring to FIGS. 3, 5, and 6, in some examples, the thermal stack 602 is coupled to the inner surface 310 of the second side 304 of the first body 202a. Specifically, the graphite sheet 604 is coupled (adhered) to the inner surface 310 of the second side 304 of the first body 202a. That is, the graphite sheet 604 is between the inner surface 310 of the second side 304 of the first body 202a and the aerogel film layer 404. In other words, the thermal stack 602 is coupled (adhered) to the inner surface of the “D” cover of the information handling system 200; and in particular, the graphite sheet 604 is coupled (adhered) to the inner surface of the “D” cover of the information handling system 200.

The thermal stack 602, similar to the thermal stack 402, is configured to reduce a skin temperature of the external surface 312 of the second side 304 of the first body 202a. That is, through the combination of the insulation of the aerogel film layer 404 and the radiation of the heat dissipating layer 406 and the graphite sheet 604, the skin temperature of the external surface 312 of the second side 304 of the first body 202a can be reduced. That is, the heat generated by the computing elements 322 can be reduced by the thermal stack 602, and in particular, through the combination of the insulation of the aerogel film layer 404 and the radiation of the heat dissipating layer 406 and graphite sheet 604. That is, the skin temperature of the external surface 312 of the second side 304 of the first body 202a that is a result of the heat generated by the computing elements 322 can be reduced by the thermal stack 402, and in particular, through the combination of the insulation of the aerogel film layer 404 and the radiation of the heat dissipating layer 406 and graphite sheet 604.

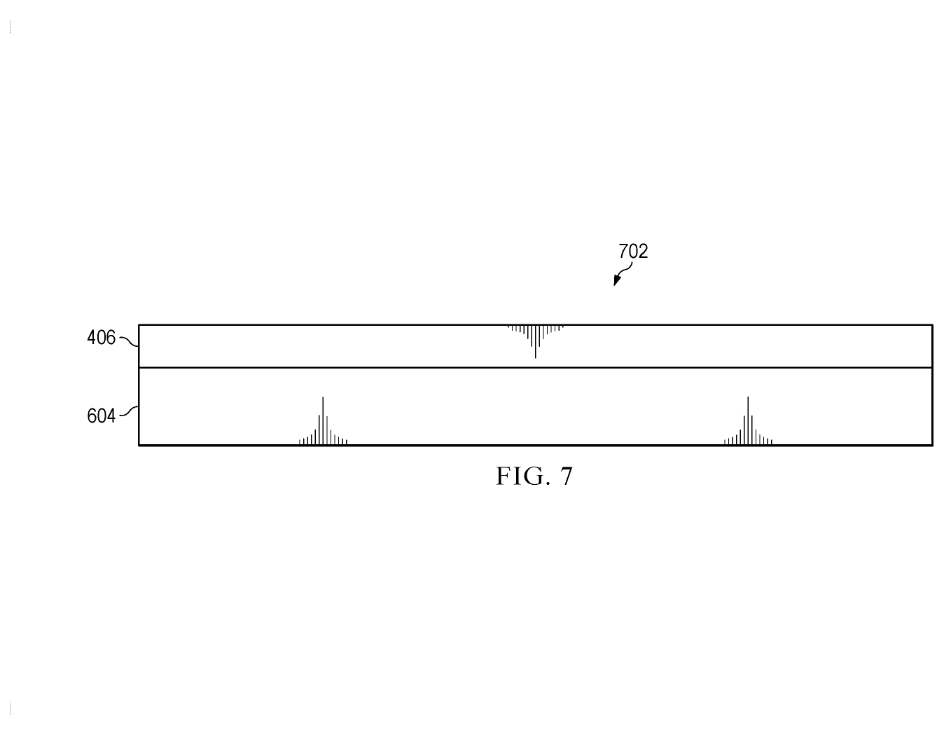

FIG. 7 is a side view of a thermal stack 702, in a third implementation. The thermal stack 702 can include the heat dissipating layer 406 and the graphite sheet 604. Referring to FIGS. 3, 5 and 7, in some examples, the thermal stack 702 is coupled to the inner surface 310 of the second side 304 of the first body 202a. Specifically, the graphite sheet 604 is coupled (adhered) to the inner surface 310 of the second side 304 of the first body 202a. That is, the graphite sheet 604 is between the inner surface 310 of the second side 304 of the first body 202a and the heat dissipating layer 406. In other words, the thermal stack 702 is coupled (adhered) to the inner surface of the “D” cover of the information handling system 200; and in particular, the graphite sheet 604 is coupled (adhered) to the inner surface of the “D” cover of the information handling system 200.

The thermal stack 702, similar to the thermal stack 402, is configured to reduce a skin temperature of the external surface 312 of the second side 304 of the first body 202a. That is, through the combination of the insulation of the radiation of the heat dissipating layer 406 and the graphite sheet 604, the skin temperature of the external surface 312 of the second side 304 of the first body 202a can be reduced. That is, the heat generated by the computing elements 322 can be reduced by the thermal stack 702, and in particular, through the combination of the radiation of the heat dissipating layer 406 and graphite sheet 604. That is, the skin temperature of the external surface 312 of the second side 304 of the first body 202a that is a result of the heat generated by the computing elements 322 can be reduced by the thermal stack 702, and in particular, through the combination of the radiation of the heat dissipating layer 406 and graphite sheet 604.

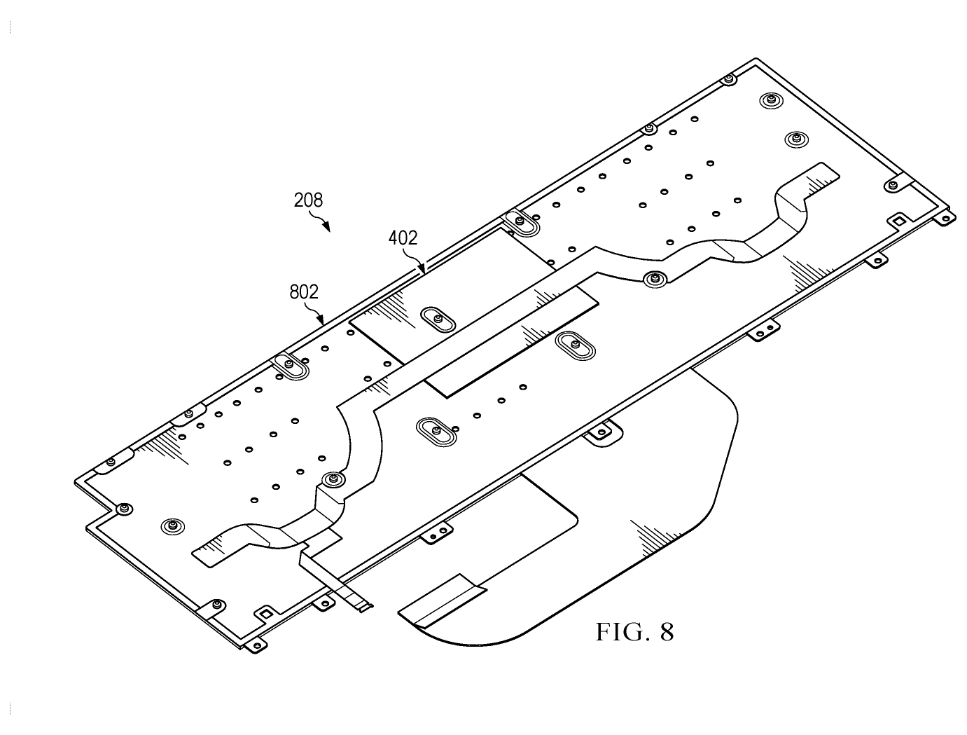

FIG. 8 is a bottom-up view of the keyboard 208 of the information handling system 200. The keyboard 208 can include a support plate 802. Referring to FIGS. 3, 4, and 8, in some examples, the thermal stack 402 is coupled to the support plate 802 of the keyboard 208. Specifically, the aerogel film layer 404 is coupled (adhered) to the support plate 802 of the keyboard 208. That is, the aerogel film layer 404 is between the support plate 802 of the keyboard 208 and the heat dissipating layer 406.

To that end, the thermal stack 402 is configured to reduce a skin temperature of the keyboard 208. That is, through the combination of the insulation of the aerogel film layer 404 and the radiation of the heat dissipating layer 406, the skin temperature of the keyboard 208 can be reduced. That is, the heat generated by the computing elements 322 can be reduced by the thermal stack 402, and in particular, through the combination of the insulation of the aerogel film layer 404 and the radiation of the heat dissipating layer 406. That is, the skin temperature of the keyboard 208 that is a result of the heat generated by the computing elements 322 can be reduced by the thermal stack 402, and in particular, through the combination of the insulation of the aerogel film layer 404 and the radiation of the heat dissipating layer 406.

Furthermore, referring to FIGS. 3, 6, and 8, the thermal stack 602 can be configured to reduce a skin temperature of the keyboard 208. The thermal stack 602 can be coupled to the support plate 802 of the keyboard 208. Specifically, the graphite sheet 604 is coupled (adhered) to the support plate 802 of the keyboard 208. That is, the graphite sheet 604 is between the support plate 802 of the keyboard 208 and the aerogel film layer 404. The thermal stack 602, similar to the thermal stack 402, is configured to reduce a skin temperature of the keyboard 208. That is, through the combination of the insulation of the aerogel film layer 404 and the radiation of the heat dissipating layer 406 and the graphite sheet 604, the skin temperature of the keyboard 208 can be reduced. That is, the heat generated by the computing elements 322 can be reduced by the thermal stack 602, and in particular, through the combination of the insulation of the aerogel film layer 404 and the radiation of the heat dissipating layer 406 and graphite sheet 604. That is, the skin temperature of the keyboard 208 that is a result of the heat generated by the computing elements 322 can be reduced by the thermal stack 602, and in particular, through the combination of the insulation of the aerogel film layer 404 and the radiation of the heat dissipating layer 406 and graphite sheet 604.

Furthermore, referring to FIGS. 3, 7, and 8, the thermal stack 702 can be configured to reduce a skin temperature of the keyboard 208. The thermal stack 702 can be coupled to the support plate 802 of the keyboard 208. Specifically, the graphite sheet 604 is coupled (adhered) to the support plate 802 of the keyboard 208. That is, the graphite sheet 604 is between the support plate 802 of the keyboard 208 and the heat dissipating layer 406. The thermal stack 702, similar to the thermal stack 402, is configured to reduce a skin temperature of the keyboard 208. That is, through the combination of the insulation of the radiation of the heat dissipating layer 406 and the graphite sheet 604, the skin temperature of the keyboard 208 can be reduced. That is, the heat generated by the computing elements 322 can be reduced by the thermal stack 702, and in particular, through the combination of the radiation of the heat dissipating layer 406 and graphite sheet 604. That is, the skin temperature of the keyboard 208 that is a result of the heat generated by the computing elements 322 can be reduced by the thermal stack 402, and in particular, through the combination of the radiation of the heat dissipating layer 406 and graphite sheet 604.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. An information handling system, comprising:
a body including a first side and a second side, the second side including an internal surface and an external surface;
one or more computing elements contained within the body, the computing elements configured to generate heat proximate to the inner surface of the second side of the body;
a thermal stack coupled to the inner surface of the second side of the body, the thermal stack including:
an aerogel film layer; and
a heat dissipating layer that is coated to the aerogel sheet such that the aerogel film layer is between the inner surface of the second side of the body and the heat dissipating layer,
wherein the thermal stack is configured to reduce a skin temperature of the external surface of the second side of the body.

2. The information handling system of claim 1, wherein the thermal stack further includes a graphite sheet such that the aerogel film layer is between the graphite sheet and the heat dissipation layer.

3. The information handling system of claim 2, wherein the graphite sheet is coupled to the inner surface of the second side of the body.

4. The information handling system of claim 1, wherein the heat dissipating layer is 0.02 millimeters thick.

5. The information handling system of claim 1, wherein the aerogel film layer is coupled to the inner surface of the second side of the body.

6. The information handling system of claim 1, wherein the heat dissipating layer is formed from at least boron nitride, graphene, and carbon fiber.

7. An information handling system, comprising:
a body including a first side and a second side;
a keyboard coupled to the body, the keyboard including a support plate;
one or more computing elements contained within the body, the computing elements configured to generate heat proximate to the keyboard;
a thermal stack coupled to the support plate, the thermal stack including:
an aerogel film layer; and
a heat dissipating layer that is coated to the aerogel sheet such that the aerogel film layer is between the support plate of the keyboard and the heat dissipating layer,
wherein the thermal stack is configured to reduce a skin temperature of the keyboard.

8. The information handling system of claim 7, wherein the thermal stack further includes a graphite sheet such that the aerogel film layer is between the graphite sheet and the heat dissipation layer.

9. The information handling system of claim 8, wherein the graphite sheet is coupled to the support plate of the keyboard.

10. The information handling system of claim 7, wherein the heat dissipating layer is 0.02 millimeters thick.

11. The information handling system of claim 7, wherein the aerogel film layer is coupled to the support plate of the keyboard.

12. The information handling system of claim 7, wherein the heat dissipating layer is formed from at least boron nitride, graphene, and carbon fiber.

13. A thermal stack for use in an information handling system, comprising:
an aerogel film layer; and
a heat dissipating layer that is coated to the aerogel sheet,
wherein the thermal stack is coupled to a surface of the information handling system,
wherein the thermal stack is configured to reduce a skin temperature at the surface of the information handling system.

14. The thermal stack of claim 13, wherein the thermal stack further includes a graphite sheet such that the aerogel film layer is between the graphite sheet and the heat dissipation layer.

15. The thermal stack of claim 13, wherein the heat dissipating layer is 0.02 millimeters thick.

16. The thermal stack of claim 13, wherein the heat dissipating layer is formed from at least boron nitride, graphene, and carbon fiber.
